(19) United States
(12) Patent Application Publication
(10) Pub. No.: US 2023/0127486 A1
(43) Pub. Date: Apr. 27, 2023

(54) SEMICONDUCTOR DEVICE

(71) Applicant: Mitsubishi Electric Corporation, Tokyo (JP)

(72) Inventors: Ayanori GATTO, Tokyo (JP); Fumihito MASUOKA, Tokyo (JP); Koji TANAKA, Tokyo (JP); Masanori TSUKUDA, Tokyo (JP)

(73) Assignee: Mitsubishi Electric Corporation, Tokyo (JP)

(21) Appl. No.: 17/813,864

(22) Filed: Jul. 20, 2022

(30) Foreign Application Priority Data
Oct. 21, 2021 (JP) 2021-172071

(51) Int. Cl. H01L 29/78; H01L 29/40; H01L 29/739

(52) U.S. Cl. CPC H01L 29/7813; H01L 29/405; H01L 29/7397; H01L 29/7811

(57) ABSTRACT

A semiconductor device according to the present disclosure includes a P layer, an insulating film, an electrode, a plurality of P- layers arranged on a side of a termination region of the P layer, an N- layer, an N++ layer, an insulating film, an electrode, a high permittivity layer disposed at least on the P- layers, and a low permittivity layer disposed on the high permittivity layer, and a distance between an end on a side of an active region of the insulating film and an end on a side of the termination region of one of the P- layers located farthest from the active region is more than µm and µm or less, and a distance between the end on the side of the active region of the insulating film and an end on a side of the active region of the electrode is 50 µm or more.

### BACKGROUND OF THE INVENTION

### Field of the Invention

The present disclosure relates to semiconductor devices.

### Description of the Background Art

A semiconductor device including a semi-insulating film disposed on a semiconductor substrate to suppress reduction in breakdown voltage has been disclosed (see Japanese Patent Application Laid-Open No. 2021-48232 and Japanese Patent Application Laid-Open No. 2020-198375, for example).

In the semiconductor device disclosed in Japanese Patent Application Laid-Open No. 2021-48232 and Japanese Patent Application Laid-Open No. 2020-198375, however, when the semi-insulating film is formed on an electrode disposed in a termination, a crack is generated at the end of the electrode, and moisture entering from the crack corrodes the electrode in some cases. In this case, the semi-insulating film can be separated from the semiconductor substrate, leading to reduction in breakdown voltage and moisture resistance of the semiconductor device.

### SUMMARY

It is an object of the present disclosure to provide a semiconductor device allowing for suppression of reduction in breakdown voltage and moisture resistance.

A semiconductor device according to the present disclosure is a semiconductor device having an active region and a termination region surrounding the active region, and includes: a substrate of a first conductivity type; a first impurity layer of a second conductivity type disposed at a surface of the substrate continuously from the active region to the termination region; a first insulating film disposed on the first impurity layer; a first electrode disposed on the first insulating film; a plurality of second impurity layers of the second conductivity type arranged at the surface of the substrate on a termination region side of the first impurity layer, and having a lower impurity concentration than the first impurity layer; a third impurity layer of the first conductivity type disposed at the surface of the substrate on a termination region side of the second impurity layers; a fourth impurity layer of the first conductivity type disposed at the surface of the substrate on a termination region side of the third impurity layer, and having a higher impurity concentration than the third impurity layer; a second insulating film disposed continuously on a portion of the third impurity layer and a portion of the fourth impurity layer; a second electrode disposed continuously on a portion of the second insulating film and the fourth impurity layer; a high permittivity layer disposed at least on the second impurity layers; and a low permittivity layer disposed on the high permittivity layer, wherein a distance between an end on an active region side of the second insulating film and an end on a termination region side of one of the second impurity layers located farthest from the active region is more than 0 µm and 10 µm or less, and a distance between the end on the active region side of the second insulating film and an end on an active region side of the second electrode is 50 µm or more.

According to the present disclosure, reduction in breakdown voltage and moisture resistance can be suppressed.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top view of a semiconductor device according to the related art;

FIG. 2 is a cross-sectional view of the semiconductor device according to the related art;

FIG. 3 is a cross-sectional view of a semiconductor device according to an embodiment;

FIG. 4 shows peak concentration ranges of diffusion layers according to the embodiment;

FIG. 5 shows refractive indices of a high permittivity layer and a low permittivity layer according to the embodiment;

FIG. 6 is a cross-sectional view of an electrode according to the embodiment;

FIG. 7 illustrates an example of a semiconductor device manufacturing process according to the embodiment;

FIG. 8 illustrates the example of the semiconductor device manufacturing process according to the embodiment;

FIG. 9 illustrates the example of the semiconductor device manufacturing process according to the embodiment;

FIG. 10 illustrates the example of the semiconductor device manufacturing process according to the embodiment;

FIG. 11 illustrates the example of the semiconductor device manufacturing process according to the embodiment;

FIG. 12 shows an equivalent circuit in a high temperature high humidity experiment of an IGBT;

FIG. 13 shows results of the high temperature high humidity experiment of semiconductor devices according to the embodiment and the semiconductor device according to the related art for comparison;

FIG. 14 is a cross-sectional view of a semiconductor device according to a modification of the embodiment; and

FIG. 15 is a cross-sectional view of a semiconductor device according to a modification of the embodiment.

### DESCRIPTION OF THE PREFERRED EMBODIMENTS

### Related Art

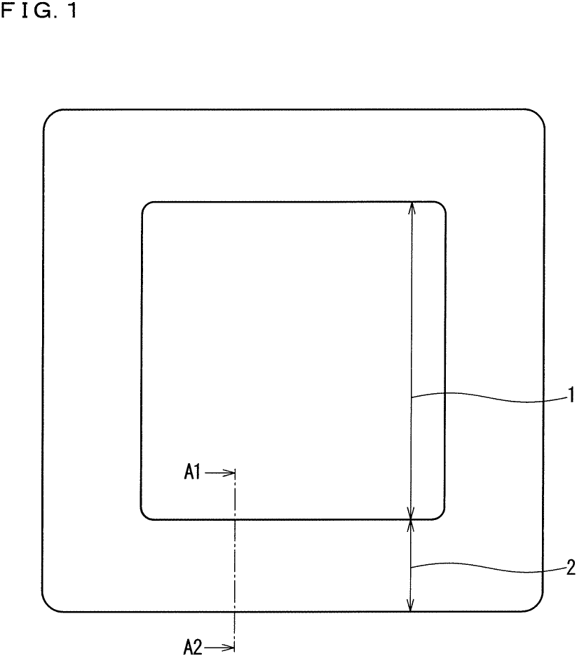

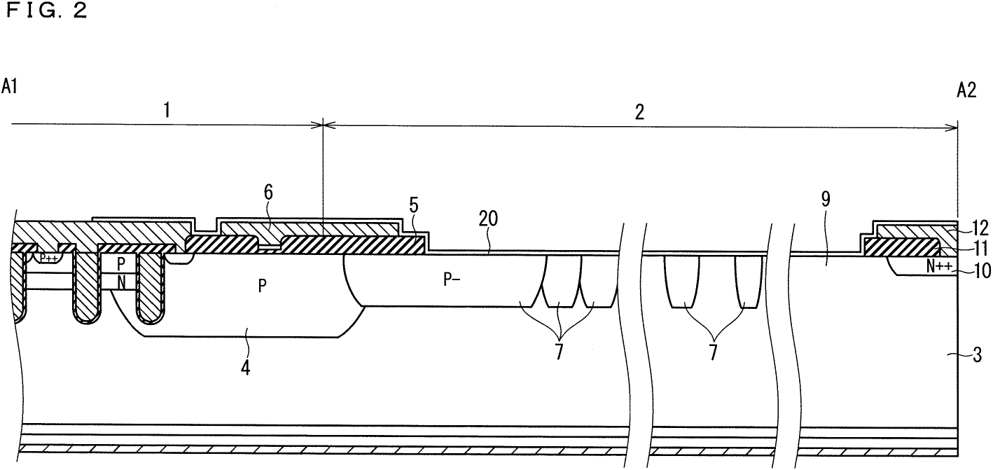

FIG. 1 is a top view of a semiconductor device according to the related art. FIG. 2 is a cross-sectional view taken along the line A1-A2 of FIG. 1. FIG. 2 illustrates an insulated gate bipolar transistor (IGBT) as the semiconductor device according to the related art.

As illustrated in FIG. 2, the semiconductor device according to the related art includes a P layer 4 disposed at the surface of an N- substrate 3 continuously from an active region 1 to a termination region 2. An insulating film 5 is disposed on the P layer 4, and an electrode 6 is disposed on the insulating film 5.

A plurality of P- layers 7 having a lower impurity concentration than the P layer 4 are arranged at the surface of the N- substrate 3 on a side of the termination region 2 of the P layer 4. An N- layer 9 is disposed on a side of the termination region 2 of the Players 7, and an N++ layer 10 is disposed on a side of the termination region 2 of the N-layer 9. An insulating film 11 is disposed continuously on a portion of the N- layer 9 and a portion of the N++ layer 10, and an electrode 12 is disposed on the insulating film 11 and the N++ layer 10. A semi-insulating film 20 is disposed on the electrode 6, the insulating film 5, the P- layers 7, the N- layer 9, the insulating film 11, and the electrode 12.

It is generally known that the semi-insulating film 20 is formed by plasma enhanced chemical vapor deposition (PECVD). In a plasma chamber during PECVD processing, accelerated ions form the compound film while damaging the surface of the N- substrate 3. In this case, interface charge Qss is accumulated at an interface between the damaged surface of the N- substrate 3 and the compound film.

In a case where a reverse voltage is applied to the semiconductor device (a breakdown voltage mode), the interface charge Qss affects depletion in a semiconductor, and makes a depletion layer more likely to extend (in a case of -Qss) or less likely to extend (in a case of +Qss). Due to variation during the PECVD processing, a value of the interface charge Qss can change, and stability of a breakdown voltage of the semiconductor device is deteriorated. Deterioration in stability of the breakdown voltage increases the influence of external charge (mobile ions in a module) at a high temperature and a high humidity to reduce the breakdown voltage.

Furthermore, due to a difference in deposition rate of the semi-insulating film 20 formed on the surface and a side of each of the electrodes 6 and 12, a crack is generated in the semi-insulating film 20 in a stepped portion at the end of each of the electrodes 6 and 12 during the PECVD processing. Once the crack is generated, moisture entering from the crack can corrode the electrodes 6 and 12 at a high temperature and a high humidity. If films of the electrodes 6 and 12 expand due to corrosion of the electrodes 6 and 12, the crack of the semi-insulating film 20 further develops to cause separation of the semi-insulating film 20 in contact with the surface of the N- substrate 3. Separation of the semi-insulating film 20 causes a change in interface charge Qss and damage to the surface of the N- substrate 3 in a separated portion of the semi-insulating film 20, leading to reduction in breakdown voltage of the semiconductor device. Moisture resistance of the semiconductor device is thereby also deteriorated.

Furthermore, in the semiconductor device according to the related art, the electrodes 6 and 12 operate as field plates, so that electric field concentration occurs at the end of each of the electrodes 6 and 12 due to a potential difference. At a high temperature and a high humidity, moisture molecules entering from the crack are polarized by a high electric field, and react with an electrode material, leading to corrosion of the electrodes 6 and 12. As described above, corrosion of the electrodes 6 and 12 can cause separation of the semi-insulating film 20 to reduce the breakdown voltage of the semiconductor device.

The present disclosure has been conceived to solve the above-mentioned problem of the semiconductor device according to the related art, and will be described in detail below.

### Embodiment

### Configuration

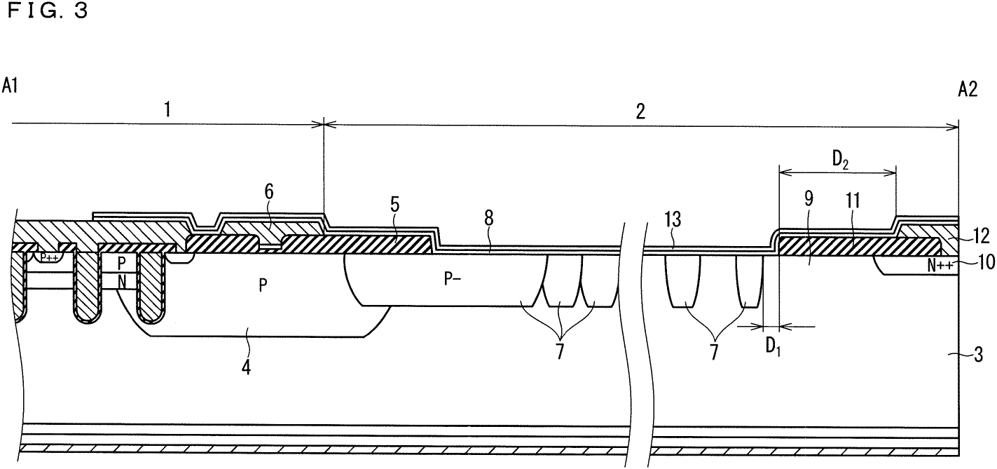

FIG. 3 is a cross-sectional view of a semiconductor device according to an embodiment, and corresponds to a cross-sectional view taken along the line A1-A2 of FIG. 1. While FIG. 3 illustrates an IGBT as the semiconductor device according to the embodiment, the semiconductor device may be a diode or a power device, such as a metal oxide semiconductor field effect transistor (MOSFET). While an N type is a first conductivity type, and a P type is a second conductivity type in description made below, the N type may be the second conductivity type, and the P type may be the first conductivity type.

The semiconductor device according to the embodiment has the active region 1 and the termination region 2 surrounding the active region 1. The P layer 4 (a first impurity layer of the second conductivity type) is disposed at the surface of the N-substrate 3 (a substrate of the first conductivity type) continuously from the active region 1 to the termination region 2. The insulating film 5 (a first insulating film) is disposed on the P layer 4, and the electrode 6 (a first electrode) is disposed on the insulating film 5.

The plurality of P- layers 7 (a plurality of second impurity layers of the second conductivity type) having a lower impurity concentration than the P layer 4 are arranged at the surface of the N- substrate 3 on a side of the termination region 2 of the P layer 4. The N- layer 9 (a third impurity layer of the first conductivity type) is disposed on a side of the termination region 2 of the P- layers 7, and the N++ layer 10 (a fourth impurity layer of the first conductivity type) having a higher impurity concentration than the N-layer 9 is disposed on a side of the termination region 2 of the N- layer 9. The insulating film 11 (a second insulating film) is disposed continuously on a portion of the N- layer 9 and a portion of the N++ layer 10, and the electrode 12 (a second electrode) is disposed on a portion of the insulating film 11 and the N++ layer 10. A high permittivity layer 8 is disposed on the electrode 6, the insulating film 5, the P- layers 7, the N- layer 9, the insulating film 11, and the electrode 12. A low permittivity layer 13 is disposed on the high permittivity layer 8.

A distance D₁ between the end on a side of the active region 1 of the insulating film 11 and the end on a side of the termination region 2 of one of the P- layers 7 located farthest from the active region 1 is more than 0 µm and 10 µm or less. A distance D₂ between the end on the side of the active region 1 of the insulating film 11 and the end on a side of the active region 1 of the electrode 12 is 50 µm or more.

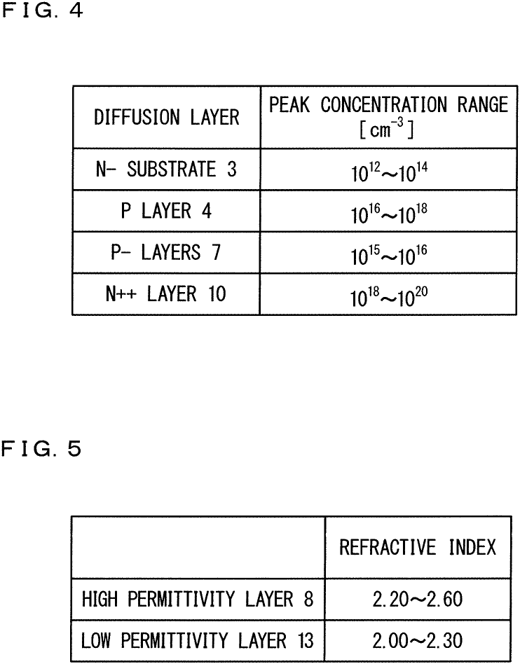

FIG. 4 shows peak concentration ranges of the N- substrate 3, the P layer 4, the P- layers 7, and the N++ layer 10 as diffusion layers.

As shown in FIG. 4, the N- substrate 3 has a peak concentration range of 10¹² to 10¹⁴ [cm⁻³], and the P layer 4 has a peak concentration range of 10¹⁶ to 10¹⁸ [cm⁻³]. The P- layers 7 have a peak concentration range of 10¹⁵ to 10¹⁶ [cm⁻³], and the N++ layer 10 has a peak concentration range of 10¹⁸ to 10²⁰ [cm⁻³].

FIG. 5 shows refractive indices of the high permittivity layer 8 and the low permittivity layer 13 at a room temperature. Permittivity increases with increasing refractive index.

As shown in FIG. 5, the high permittivity layer 8 has a refractive index of 2.20 to 2.60, and the low permittivity layer 13 has a refractive index of 2.00 to 2.30.

### Action of High Permittivity Layer 8 and Low Permittivity Layer 13

In the breakdown voltage mode, the high electric field is generated at the end on the side of the termination region 2 of one of the P- layers 7 located farthest from the active region 1 to cause a hot electron phenomenon. Electrons accelerated by the high electric field enter the insulating film 11 beyond a potential barrier between the N- layer 9 and the insulating film 11 with a certain probability, and charge up the insulating film 11. When the reverse voltage is applied for a long period of time, charge of the insulating film 11 is accumulated, leading to reduction in breakdown voltage of the semiconductor device. To counteract this, the high permittivity layer 8 is disposed to be in contact with the surface of the N- substrate 3. This can produce an effect of mitigating charge up of the insulating film 11 caused by generation of the high electric field at the end on the side of the termination region 2 of one of the P- layers 7 located farthest from the active region 1.

The high permittivity layer 8 is formed by PECVD. The surface of the N-layer 9 can be damaged during the PECVD processing to form the high permittivity layer 8, and the interface charge Qss can be accumulated at the surface of the damaged N-layer 9.

The low permittivity layer 13 is a protective layer for the high permittivity layer 8, and is formed by PECVD. A laminated structure of the high permittivity layer 8 and the low permittivity layer 13 produces an effect of improving the strength of the layers.

Furthermore, the low permittivity layer 13 can prevent generation of a crack of the high permittivity layer 8. To prevent generation of the crack of the high permittivity layer 8, the low permittivity layer 13 preferably has a thickness of 800 nm or more. By preventing generation of the crack of the high permittivity layer 8, corrosion of the electrodes 6 and 12 is suppressed, and reduction in breakdown voltage of the semiconductor device at a high temperature and a high humidity can be prevented.

### Allowable Range of Distance D₁

As described above, the distance D₁ is the distance between the end on the side of the active region 1 of the insulating film 11 and the end on the side of the termination region 2 of one of the P- layers 7 located farthest from the active region 1.

In a case where the distance D₁ is 0 µm or less, the hot electron phenomenon is caused at the end on the side of the termination region 2 of one of the P- layers 7 located farthest from the active region 1 when the reverse voltage is applied for the long period of time. The electrons accelerated by the high electric field charge up the insulating film 11, eventually leading to reduction in breakdown voltage of the semiconductor device. The distance D₁ is thus preferably more than 0 µm and more preferably 2 µm or more.

On the other hand, with increasing distance D₁, the area of contact between the N- layer 9 and the high permittivity layer 8 increases, and thus the influence of variation of the interface charge Qss increases. The distance D₁ is thus preferably shorter in view of stability of the breakdown voltage of the semiconductor device, and, specifically, is preferably 10 µm or less.

### Allowable Range of Distance D₂

As described above, the distance D₂ is the distance between the end on the side of the active region 1 of the insulating film 11 and the end on the side of the active region 1 of the electrode 12.

Due to a mechanism for deterioration of moisture resistance described as a problem of the semiconductor device according to the related art, when the distance D₂ decreases, a separated portion of the high permittivity layer 8 extends to an interface between the high permittivity layer 8 and the N- layer 9, leading to reduction in breakdown voltage of the semiconductor device.

To address the problem, the distance D₂ is set to 50 µm or more. Thus, even if the high permittivity layer 8 on the insulating film 11 is separated, the separated portion does not extend to the interface between the high permittivity layer 8 and the N- layer 9, so that reduction in breakdown voltage of the semiconductor device can be prevented.

### Relationship between End on Side of Termination Region 2 of Insulating Film 5 and End on Side of Termination Region 2 of Electrode 6

Variation of the interface charge Qss mainly affects the N- layer 9 as the surface of the N- substrate 3 having a low impurity concentration. An N- portion is small in the active region 1, so that there is no need to define a distance between the end on the side of the termination region 2 of the insulating film 5 and the end on the side of the termination region 2 of the electrode 6.

### Correlation between Electrode 6 and P Layer 4 and Correlation between Electrode 12 and N++ Layer 10

In the semiconductor device according to the related art, the electrodes 6 and 12 operate as the field plates, and thus the electric field concentration occurs at the end of each of the electrodes 6 and 12 due to the potential difference, and the electrodes 6 and 12 are likely to corrode at a location where the electric field concentration occurs. Corrosion of the electrodes 6 and 12 eventually reduces the breakdown voltage of the semiconductor device.

To address the problem, in the semiconductor device according to the embodiment, the end on the side of the termination region 2 of the P layer 4 is located farther from the active region 1 than the end on the side of the termination region 2 of the electrode 6 is. The electric field concentration at the end on the side of the termination region 2 of the electrode 6 can thereby be mitigated to suppress corrosion of the electrode 6.

Similarly, the end on the side of the active region 1 of the N++ layer 10 is located closer to the active region 1 than the end on the side of the active region 1 of the electrode 12. The electric field concentration at the end on the side of the active region 1 of the electrode 12 can thereby be mitigated to suppress corrosion of the electrode 12.

### Shapes of Electrodes 6 and 12

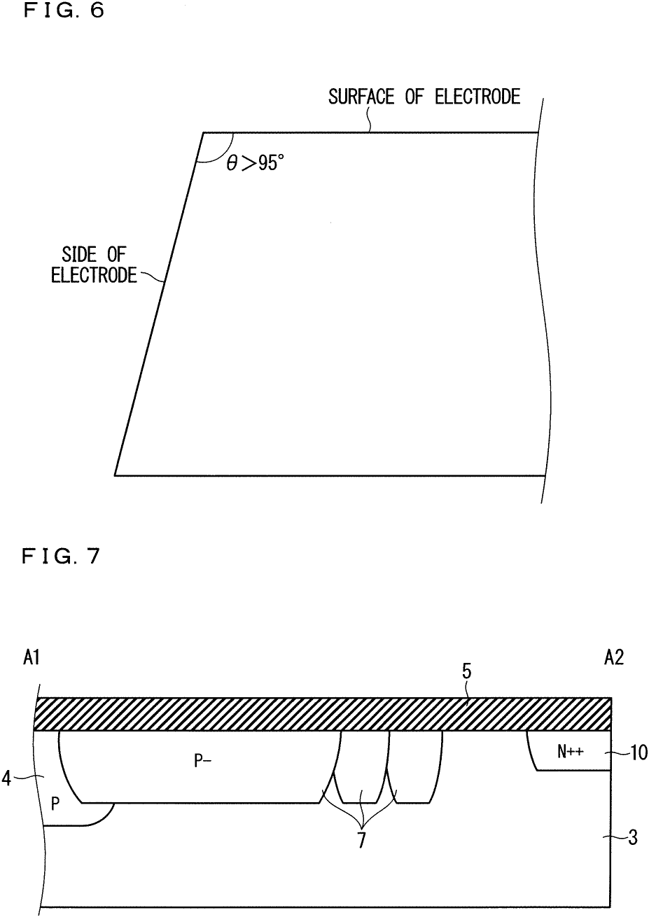

FIG. 6 is a cross-sectional view of each of the electrodes 6 and 12. As illustrated in FIG. 6, an angle between the surface and a side of each of the electrodes 6 and 12 is preferably 95° or more. Specifically, an angle between the surface and the side at the end on the side of the termination region 2 of the electrode 6 is preferably 95° or more, and an angle between the surface and the side at the end on the side of the active region 1 of the electrode 12 is preferably 95° or more.

The electric field concentration at the end of each of the electrodes 6 and 12 can thereby be mitigated to suppress corrosion of the electrodes 6 and 12 to thereby prevent separation of the high permittivity layer 8.

### Process

FIGS. 7 to 11 illustrate an example of a semiconductor device manufacturing process according to the embodiment, and illustrate formation of the insulating films 5 and 11, the electrode 12, the high permittivity layer 8, and the low permittivity layer 13.

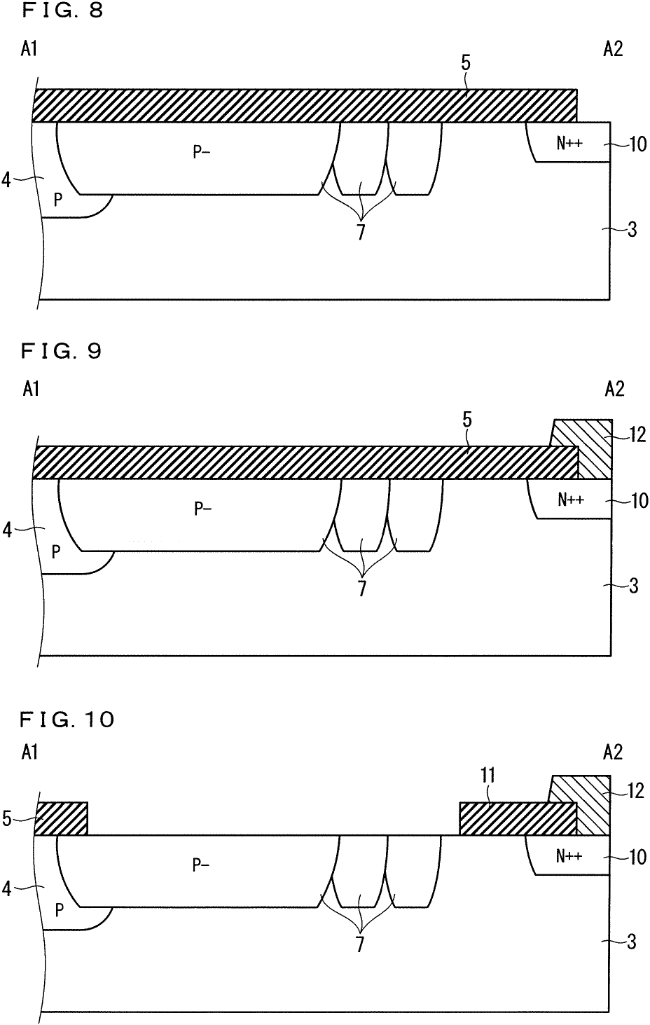

As illustrated in FIG. 7, the insulating film 5 is formed on the N- substrate 3. Next, as illustrated in FIG. 8, a portion of the insulating film 5 formed on the N++ layer 10 is etched.

Next, as illustrated in FIG. 9, the electrode 12 is formed on the N++ layer 10 and a portion of the insulating film 5. Specifically, a metal film is formed on the insulating film 5 and the N++ layer 10 by sputtering, and is then patterned to form the electrode 12. In this case, the electrode 6 may be formed simultaneously.

Next, as illustrated in FIG. 10, the insulating film 5 is etched to form the insulating films 5 and 11. Examples of etching of the insulating film 5 include plasma etching using a reactive gas, wet etching using a chemical solution, and a combination of them.

Next, as illustrated in FIG. 11, the high permittivity layer 8 and the low permittivity layer 13 are sequentially formed by PECVD.

### Effects

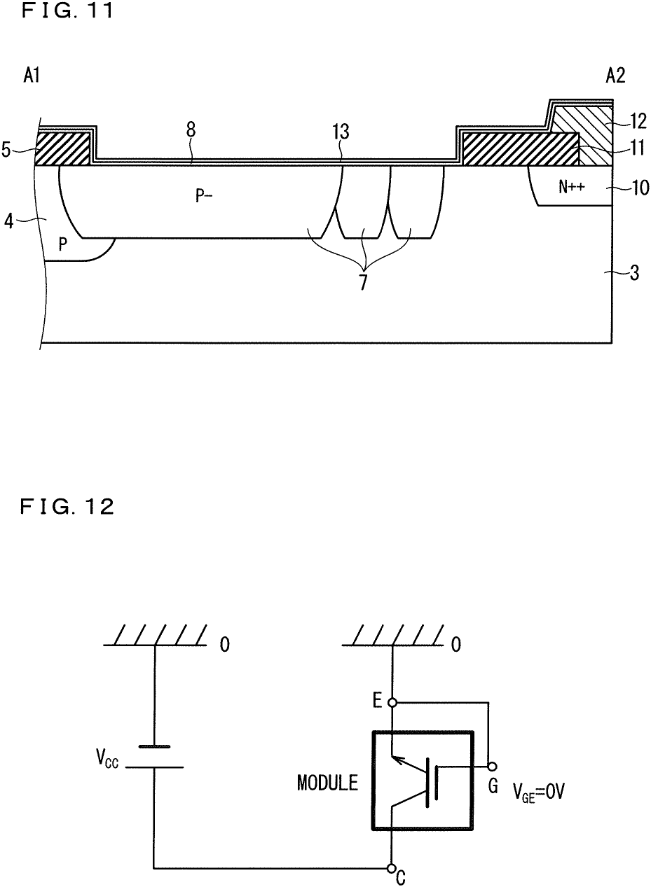

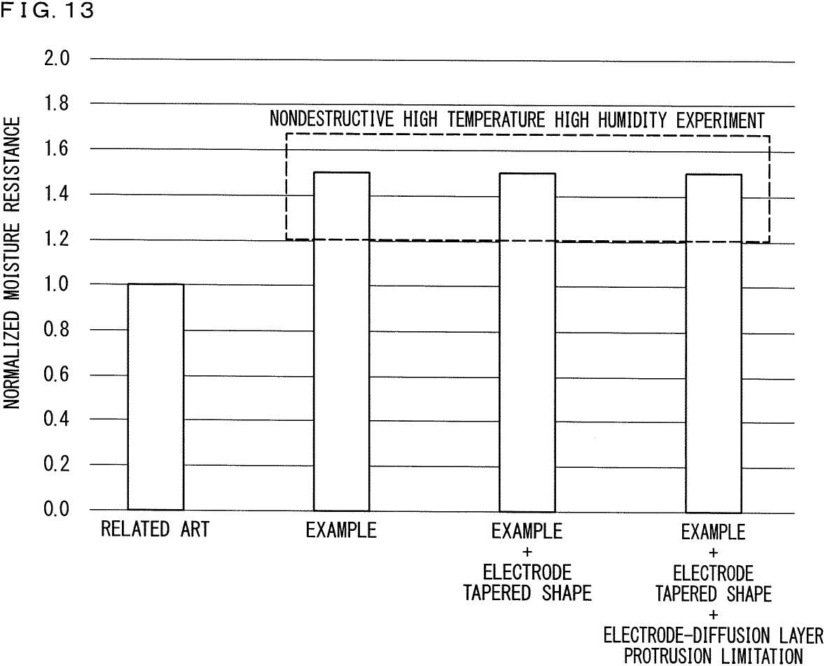

FIG. 12 shows an equivalent circuit in a high temperature high humidity experiment of the IGBT. A module in FIG. 12 corresponds to the semiconductor device according to the embodiment as the IGBT. A condition for a moisture resistance experiment includes a temperature of 150° C., a humidity of 85%, and a voltage Vcc being a rated voltage × 85%.

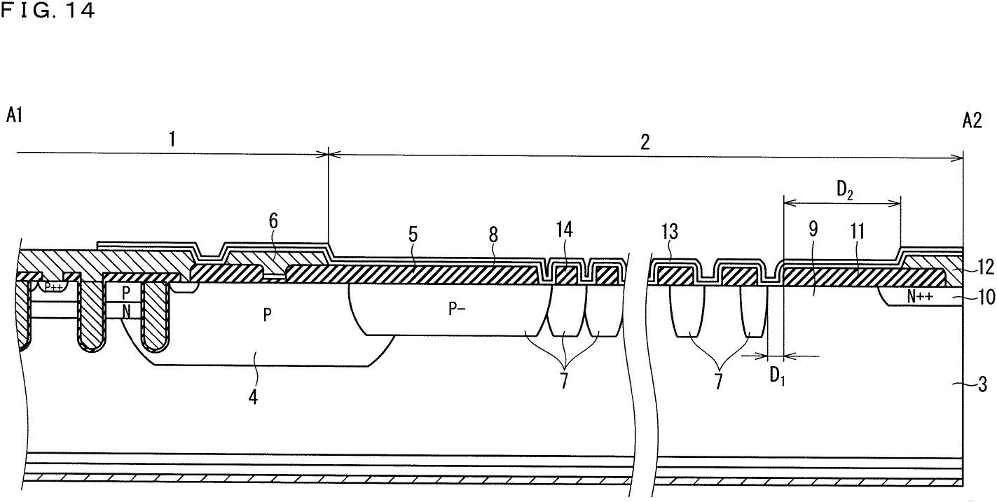

FIG. 13 shows results of the moisture resistance experiment of semiconductor devices according to the embodiment and the semiconductor device according to the related art for comparison. In FIG. 13, a term “EXAMPLE” indicates that the distances D₁ and D₂ in the semiconductor device illustrated in FIG. 3 are defined, and the other configuration is similar to that of the semiconductor device according to the related art illustrated in FIG. 2. A term “EXAMPLE + ELECTRODE TAPERED SHAPE” indicates that the distances D₁ and D₂ in the semiconductor device illustrated in FIG. 3 are defined, the angle between the surface and the side at the end of each of the electrodes 6 and 12 is 95° or more (see FIG. 6), and the other configuration is similar to that of the semiconductor device according to the related art illustrated in FIG. 2. A term “EXAMPLE + ELECTRODE TAPERED SHAPE + ELECTRODE-DIFFUSION LAYER PROTRUSION LIMITATION” indicates that the distances D₁ and D₂ in the semiconductor device illustrated in FIG. 3 are defined, the angle between the surface and the side at the end of each of the electrodes 6 and 12 is 95° or more (see FIG. 6), the end on the side of the termination region 2 of the P layer 4 is located farther from the active region 1 than the end on the side of the termination region 2 of the electrode 6 is, and the end on the side of the active region 1 of the N++ layer 10 is located closer to the active region 1 than the end on the side of the active region 1 of the electrode 12 is (the configuration illustrated in FIG. 3).

As shown in FIG. 13, the semiconductor devices according to the embodiment suppress the influence of external charge at a high temperature and a high humidity, and have moisture resistance that is 1.5 times or more moisture resistance of the semiconductor device according to the related art. Stability of the breakdown voltage of the semiconductor devices according to the embodiment is thereby improved.

### Modifications

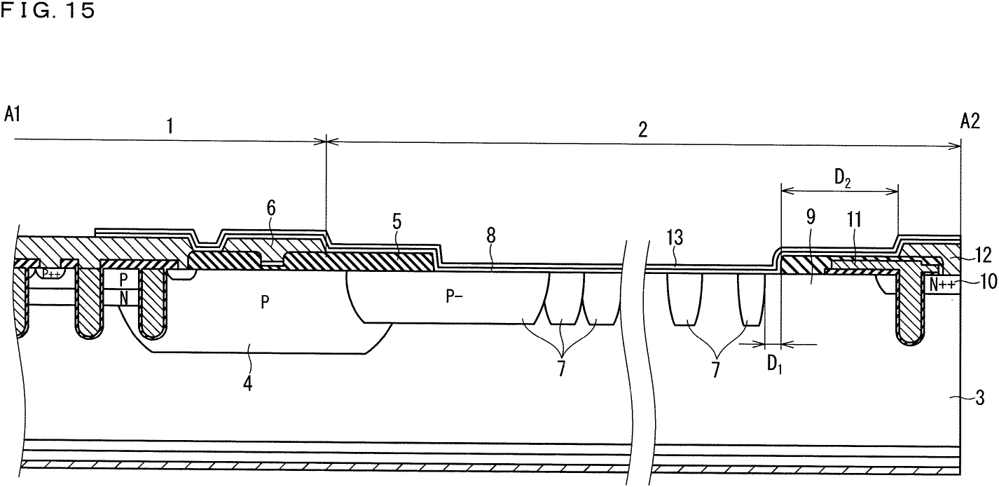

FIG. 14 is a cross-sectional view of a semiconductor device according to a modification. In the semiconductor device illustrated in FIG. 14, an insulating film 14 (a third insulating film) is disposed on a portion of the P- layers 7, and the high permittivity layer 8 is disposed continuously on the P- layers 7 and the insulating film 14. The other configuration is similar to the configuration illustrated in FIG. 3.

FIG. 15 is a cross-sectional view of a semiconductor device according to a modification. The semiconductor device illustrated in FIG. 15 includes a trench field plate in the termination region 2. The other configuration is similar to the configuration illustrated in FIG. 3.

The semiconductor devices according to the modifications illustrated in FIGS. 14 and 15 produce effects similar to the effect produced by the semiconductor device according to the embodiment illustrated in FIG. 3.

Embodiments can be modified or omitted as appropriate within the scope of the present disclosure.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device having an active region and a termination region surrounding the active region, the semiconductor device comprising:
a substrate of a first conductivity type;
a first impurity layer of a second conductivity type, the first impurity layer being disposed at a surface of the substrate continuously from the active region to the termination region;
a first insulating film disposed on the first impurity layer;
a first electrode disposed on the first insulating film;
a plurality of second impurity layers of the second conductivity type, the second impurity layers being arranged at the surface of the substrate on a termination region side of the first impurity layer, and having a lower impurity concentration than the first impurity layer;
a third impurity layer of the first conductivity type, the third impurity layer being disposed at the surface of the substrate on a termination region side of the second impurity layers;
a fourth impurity layer of the first conductivity type, the fourth impurity layer being disposed at the surface of the substrate on a termination region side of the third impurity layer, and having a higher impurity concentration than the third impurity layer;
a second insulating film disposed continuously on a portion of the third impurity layer and a portion of the fourth impurity layer;
a second electrode disposed continuously on a portion of the second insulating film and the fourth impurity layer;
a high permittivity layer disposed at least on the second impurity layers; and
a low permittivity layer disposed on the high permittivity layer, wherein
a distance between an end on an active region side of the second insulating film and an end on a termination region side of one of the second impurity layers located farthest from the active region is more than 0 µm and 10 µm or less, and
a distance between the end on the active region side of the second insulating film and an end on an active region side of the second electrode is 50 µm or more.

2. The semiconductor device according to claim 1, wherein
an end on a termination region side of the first impurity layer is located farther from the active region than an end on a termination region side of the first electrode is, and
an end on an active region side of the fourth impurity layer is located closer to the active region than an end on an active region side of the second electrode is.

3. The semiconductor device according to claim 1, wherein
an angle between a surface and a side at an end on a termination region side of the first electrode is 95° or more, and
an angle between a surface and a side at an end on an active region side of the second electrode is 95° or more.

4. The semiconductor device according to claim 1, wherein
the low permittivity layer has a thickness of 800 nm or more.

5. The semiconductor device according to claim 1, wherein
the high permittivity layer has a refractive index of 2.20 to 2.60, and
the low permittivity layer has a refractive index of 2.00 to 2.30.

6. A semiconductor device having an active region and a termination region surrounding the active region, the semiconductor device comprising:
a substrate of a first conductivity type;
a first impurity layer of a second conductivity type, the first impurity layer being disposed at a surface of the substrate continuously from the active region to the termination region;
a first insulating film disposed on the first impurity layer;
a first electrode disposed on the first insulating film;
a plurality of second impurity layers of the second conductivity type, the second impurity layers being arranged at the surface of the substrate on a termination region side of the first impurity layer, and having a lower impurity concentration than the first impurity layer;
a third impurity layer of the first conductivity type, the third impurity layer being disposed at the surface of the substrate on a termination region side of the second impurity layers;
a fourth impurity layer of the first conductivity type, the fourth impurity layer being disposed at the surface of the substrate on a termination region side of the third impurity layer, and having a higher impurity concentration than the third impurity layer;
a second insulating film disposed continuously on a portion of the third impurity layer and a portion of the fourth impurity layer;
a second electrode disposed continuously on a portion of the second insulating film and the fourth impurity layer;
a third insulating film disposed on a portion of the second impurity layers;
a high permittivity layer disposed continuously at least on the second impurity layers and the third insulating film; and
a low permittivity layer disposed on the high permittivity layer, wherein
a distance between an end on an active region side of the second insulating film and an end on a termination region side of one of the second impurity layers located farthest from the active region is more than 0 µm and 10 µm or less, and
a distance between the end on the active region side of the second insulating film and an end on an active region side of the second electrode is 50 µm or more.

7. The semiconductor device according to claim 6, wherein
an end on a termination region side of the first impurity layer is located farther from the active region than an end on a termination region side of the first electrode is, and
an end on an active region side of the fourth impurity layer is located closer to the active region than an end on an active region side of the second electrode is.

8. The semiconductor device according to claim 6, wherein
an angle between a surface and a side at an end on a termination region side of the first electrode is 95° or more, and
an angle between a surface and a side at an end on an active region side of the second electrode is 95° or more.

9. The semiconductor device according to claim 6, wherein
the low permittivity layer has a thickness of 800 nm or more.

10. The semiconductor device according to claim 6, wherein
the high permittivity layer has a refractive index of 2.20 to 2.60, and
the low permittivity layer has a refractive index of 2.00 to 2.30.
